(19) United States
(12) Patent Application Publication
(10) Pub. No.: US 2018/0210248 A1
(43) Pub. Date: Jul. 26, 2018

(54) Array Substrate And Liquid Crystal Display Panel

(71) Applicant: Wujan China Star Optoelectronics Technology Co., Ltd., Wuhan, Hubei (CN)

(72) Inventor: Yingtao XIE, Shenzhen, Guangdong (CN)

(73) Assignee: Wuhan China Star Optoelectronics Technology Co., L td., Wuhan, Hubei (CN)

(21) Appl. No.: 15/322,398

(22) PCT Filed: Nov. 16, 2016
(86) PCT No.: PCT/CN2016/106033

§ 371 Date: Dec. 27, 2016

(30) Foreign Application Priority Data
Aug. 26, 2016 (CN) 2016107426521

(51) Int. Cl. G02F 1/1368; G02F 1/1362; H01L 29/786; H01L 27/12; H01L 29/423; H01L 29/66; H01L 21/02

(52) U.S. Cl. CPC G02F 1/1368; G02F 1/136227; H01L 29/78693; H01L 27/1225; H01L 29/42356; H01L 29/45; H01L 29/66969; H01L 27/1262; H01L 21/02274; H01L 21/02345; H01L 27/1248

(57) ABSTRACT

The present invention provides an array substrate and a liquid display panel, the array substrate comprises: a passivation layer or a gate insulator layer are formed by radio frequency and annealing under the presence of compressed air after forming the oxide semiconductor material layer. By this way, it can regulate difference between threshold voltages of the plurality of oxide thin film transistors, and it can further reduce drift of threshold voltages of oxide semiconductor TFT, to achieve providing a base of a uniform display technology.

### FIELD OF THE INVENTION

The present invention relates to a technology of liquid crystal display, and more particularly, to an array substrate and a liquid crystal display panel.

### DESCRIPTION OF PRIOR ART

Oxide semiconductor thin film transistor (TFT) is gradually becoming a powerful competitorin next-generation display technology with some advantages such as high mobility, relatively inexpensive in large area production and so on.

However, the present situation is that the threshold voltages of the oxide semiconductor TFT on panel is drifted and the difference between the threshold voltages of the respective oxide semiconductor TFTs is large and uneven. It brings about a bad influence in the quality and effect of the liquid crystal display.

### SUMMARY OF THE INVENTION

Technical problem resolved by the present invention is to provide an array substrate and a liquid crystal display panel, which can regulate difference between threshold voltages of the plurality of oxide TFTs, and it can further reduce drift of threshold voltages of oxide semiconductor TFT, to achieve providing a base of a uniform display technology.

In order to solve deficiencies of prior art, the purpose of the present invention is to provide an array substrate, and on the array substrate, a plurality of oxide TFTs is arranged in an array, wherein the array substrate comprises:

a substrate;

a gate layer is formed on the substrate;

a gate insulating layer covers the substrate and the gate layer;

an oxide semiconductor material layer is formed on the gate insulating layer and located directly above the gate layer;

a source layer and a drain layer are formed on the gate insulating layer separately and respectively, and cover a part of the oxide semiconductor material layer respectively, in a way so that source layer and the drain layer are located on both sides of the oxide semiconductor material layer respectively;

a passivation layer covers the source layer, the drain layer, and the oxide semiconductor material layer, the passivation layer is formed by radio frequency and annealing under the presence of compressed air, so as to regulate difference between threshold voltages of the plurality of oxide TFTs;

an over coat covers the passivation layer, a contact hole which passes through the over coatis arranged in the over coat, a first end of the contact hole extends and passes through the passivation layer and is connected to the drain layer, the material which filled in the contact hole is a transparent electrode material; and

a pixel electrode layer is formed on the over coat and made from a transparent electrode material, the pixel electrode layer is connected to the second end of the contact hole, so as to achieve the electrical connection between the drain layer and the pixel electrode layer.

Wherein the power of the radio frequency is in the range of 400 W to 4000 W.

Wherein the power of the radio frequency is 600 W, 1000 W and 1400 W respectively.

Wherein the annealing temperature is in the range of 200 to 400° C.

In order to solve deficiencies of prior art, the purpose of the present invention is to further provide a liquid crystal display panel which comprises:

a first substrate;

a second substrate is arranged opposite to the first substrate, and on the second substrate, a plurality of oxide TFTs is arranged in an array, wherein the second substrate comprises:

a substrate;

a gate layer is arranged on the substrate;

a gate insulating layer covers the substrate and the gate layer;

an oxide semiconductor material layer is arranged on the gate insulating layer and located directly above the gate layer;

a source layer and a drain layer are arranged on the gate insulating layer separately and respectively, and cover a part of the oxide semiconductor material layer respectively, in a way so that source layer and the drain layer are located on both sides of the oxide semiconductor material layer respectively;

a passivation layer coves the source layer, the drain layer, and the oxide semiconductor material layer, the passivation layer is formed by radio frequency and annealing under the presence of compressed air, so as to regulate difference between threshold voltages of the plurality of oxide TFTs;

an over coat covers the passivation layer, a contact hole which passes through the over coatis arranged in the over coat, a first end of the contact hole extends and passes through the passivation layer and is connected to the drain layer, the material which filled in the contact hole is a transparent electrode material;

a pixel electrode layer is arranged on the over coat and made from a transparent electrode material, the pixel electrode layer is connected to the second end of the contact hole, so as to achieve the electrical connection between the drain layer and the pixel electrode layer; and

a liquid crystal layer is arranged between the first substrate and the second substrate.

In order to solve deficiencies of prior art, the purpose of the present invention is to more further provide an array substrate, and on the array substrate, a plurality of oxide TFTs is arranged in an array, wherein the array substrate comprises:

a substrate;

an insulating buffer layer covers the substrate;

an oxide semiconductor material layer, which comprises a channel region, a source region, and a drain region, the oxide semiconductor material layer is arranged on the insulating buffer layer, and wherein the source region and the drain region are located on both sides of the channel region respectively, the source region and the drain region are formed by doping the oxide semiconductor material;

a gate insulating layer covers the channel region, and wherein the gate insulating layer is formed by radio frequency and annealing under the presence of compressed air, so as to regulate difference between threshold voltages of the plurality of oxide TFTs;

a gate layer covers the gate insulating layer;

an insulated interconnection layer covers the buffer layer, the source region, the gate layer, and the drain region, and a first contact hole and a second contact hole which pass through the interconnection layer are arranged in the interconnection layer respectively, a first end of the first contact hole is connected to the source region and a first end of the second contact hole is connected to the drain region, wherein the material which filled in the first and second contact holes is a transparent electrode material; and

a source layer and a drain layer are arranged on the interconnection layer separately and respectively and made from a transparent electrode material, wherein the source layer is connected to the second end of the first contact hole, so as to achieve the electrical connection between the source layer and the source region, and wherein the drain layer is connected to the second end of the second contact hole, so as to achieve the electrical connection between the drain layer and the drain region.

Wherein the power of the radio frequency is in the range of 400 W to 4000 W.

Wherein the power of the radio frequency is 600 W, 1000 W and 1400 W respectively.

Wherein the annealing temperature is in the range of 200 to 400° C.

The present invention can be concluded with the following advantages: the present invention is different from the prior art that after forming an oxide semiconductor material layer, a gate insulating layer is formed by radio frequency and annealing under the presence of compressed air. By this way, it can regulate difference between threshold voltages of the plurality of oxide TFTs, and it can further reduce drift of threshold voltages of oxide semiconductor TFT, to achieve providing a base of a uniform display technology.

### BRIEF DESCRIPTION OF DRAWINGS

FIG. 1 is an illustrational view of the array substrate in accordance with preferred embodiment of the present invention;

FIG. 2 is an illustrational view of the first portion of a manufacturing process of the array substrate in accordance with FIG. 1 in a practical application;

FIG. 3 is an illustrational view of the second portion of a manufacturing process of the array substrate in accordance with FIG. 1 in a practical application;

FIG. 4 is an illustrational view of the locations of testing TFT devices on the substrate made by manufacturing process of FIGS. 2 and 3;

FIG. 5 is a plot of current and voltage (IdVg) at 600 W for the TFT device of FIG. 4;

FIG. 6 is a plot of current and voltage (IdVg) at 1000 W for the TFT device of FIG. 4;

FIG. 7 is a plot of current and voltage (IdVg) at 1400 W for the TFT device of FIG. 4;

FIG. 8 is an illustrational view of the array substrate in accordance with further embodiment of the present invention;

FIG. 9 is an illustrational view of the first portion of a manufacturing process of the array substrate in accordance with FIG. 8 in a practical application; and

FIG. 10 is an illustrational view of the second portion of a manufacturing process of the array substrate in accordance with FIG. 8 in a practical application.

### DESCRIPTION OF PREFERRED EMBODIMENT

Technical implementation will be described below clearly and fully by combining with drawings made in accordance with an embodiment in the present invention.

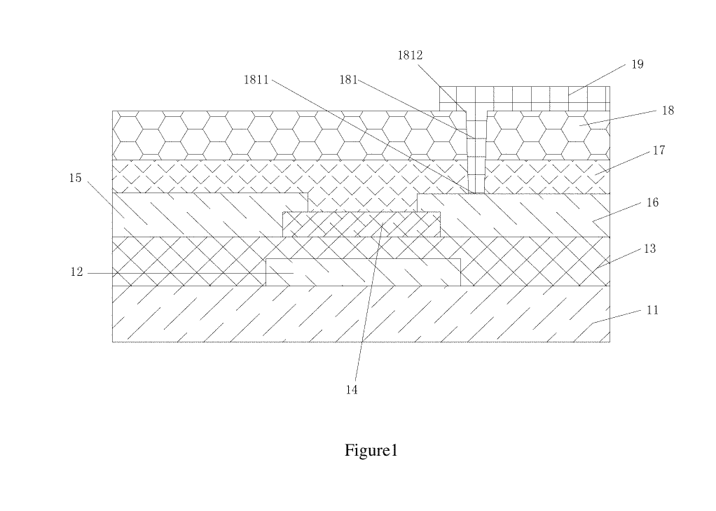

Referring to FIG. 1, FIG. 1 is an illustrational view of the array substrate in accordance with preferred embodiment of the present invention. Wherein on the array substrate, a plurality of oxide TFTs is arranged in an array, and wherein the array substrate comprises: a substrate 11, a gate layer 12, a gate insulating layer 13, an oxide semiconductor material layer 14, a source layer 15, a drain layer 16, a passivation layer 17, an over coat 18 and a pixel electrode layer 19.

The gate layer 12 is formed on the substrate 11 and which is made from metal conductor materials.

The gate insulating layer 13 covers the substrate 11 and the gate layer 12. The gate insulating layer 13 may be made from silicon oxide thin films, and which thickness may be less than 500 nm.

The oxide semiconductor material layer 14 is formed on the gate insulating layer 13 and located directly above the gate layer 12. Materials of the oxide semiconductor material layer 14, include, but are not limited to amorphous indium-gallium-zinc-oxide.

The source layer 15 and the drain layer 16 are formed on the gate insulating layer 13 separately and respectively, and cover a part of the oxide semiconductor material layer 14 respectively, in a way so that source layer 15 and the drain layer 16 are located on both sides of the oxide semiconductor material layer 14 respectively. The source layer 15 and the drain layer are made from metal conductor materials such as molybdenum, copper, or molybdenum/copper alloys.

The passivation layer 17 covers the source layer 15, the drain layer 16, and the oxide semiconductor material layer 14, the passivation layer 17 is formed by radio frequency and annealing under the presence of compressed air, so as to regulate difference between threshold voltages of the plurality of oxide TFTs. In a practical application, the difference between threshold voltages of the plurality of oxide TFTs can be regulated in accordance with actual needs by regulating the power of the radio frequency, annealing under the presence of compressed air, regulating the annealing temperature and the annealing time.

The over coat 18 covers the passivation layer 17, a contact hole 181 which passes through the over coat 18 is arranged in the over coat 18, a first end 1811 of the contact hole 181 extends and passes through the passivation layer 17 and is connected to the drain layer 16, the material which filled in the contact hole 181 is a transparent electrode material.

The pixel electrode layer 19 is formed on the over coat 18 and made from a transparent electrode material, the pixel electrode layer 19 is connected to the second end 1812 of the contact hole 181, so as to achieve the electrical connection between the drain layer 16 and the pixel electrode layer 19.

Wherein the power of the radio frequency is in the range of 400 W to 4000 W. Further, the power of the radio frequency is 600 W, 1000 W and 1400 W respectively.

Wherein the annealing temperature is in the range of 200 to 400° C. Further, the annealing temperature is 350° C.

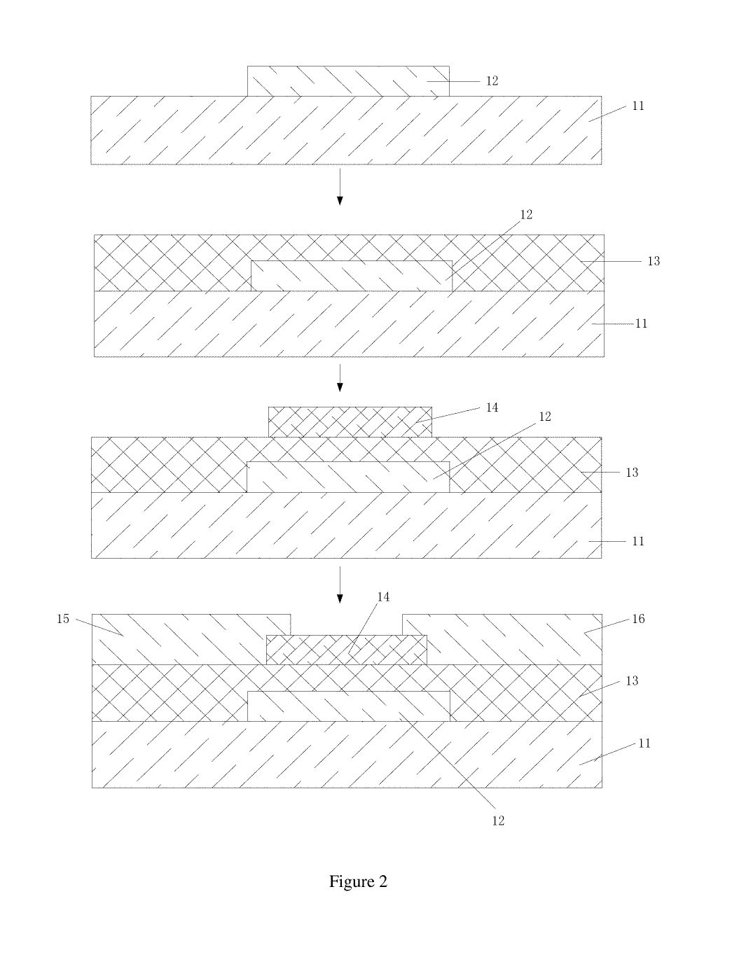

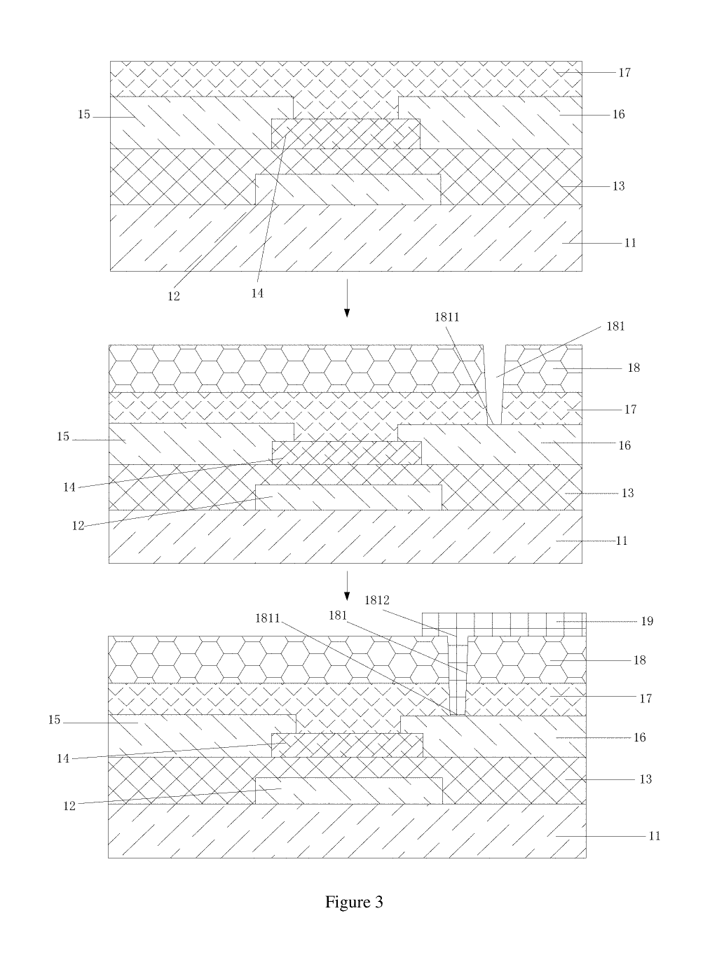

In an actual application, the array substrate described above can be manufactured by the following manufacturing process, as shown in FIGS. 2 and 3:

(1) depositing a metal gate electrode thin film layer on the substrate 11 based on a physical vapor deposition (PVD) method and patterning by a standard photolithography process to obtain the gate layer 12;

(2) depositing the gate insulator layer 13 of silicon oxide thin film on the substrate 11 and the gate layer 12 by a chemical vapor deposition (CVD) method, which thickness is less than 500 nm;

(3) depositing an oxide semiconductor (e.g., amorphous indium-gallium-zinc-oxide) thin film on the gate insulating layer 13 based on the PVD method and then forming a required amorphous indium-gallium-zinc-oxide pattern by a standard photolithographic process to obtain the oxide semiconductor material layer 14;

(4) depositing a source and drain electrode thin film layer of metal (such as molybdenum, copper, or molybdenum/copper alloys) on the gate insulating layer 13 based on the PVD method, and patterning by a standard photolithography process to obtain the source layer 15 and the drain layer 16;

(5) depositing the passivation layer 17 by a plasma enhanced chemical vapor deposition (PECVD) method, wherein the passivation layer 17 is formed by radio frequency and annealing under the presence of compressed air;

(6) depositing silicon oxide by the PECVD method to obtain the over coat 18, or depositing an organic over coat 18 by a coating method, and the over coat 18 and the passivation layer 17 is opened to obtain the contact hole 181 located in the drain layer 16 by a standard photolithography process;

(7) depositing indium tin oxide and patterning by a standard photolithography process to form a pixel electrode layer 19 located in which connected to the drain layer 16, thereby the manufacturing process of the array substrate is completed.

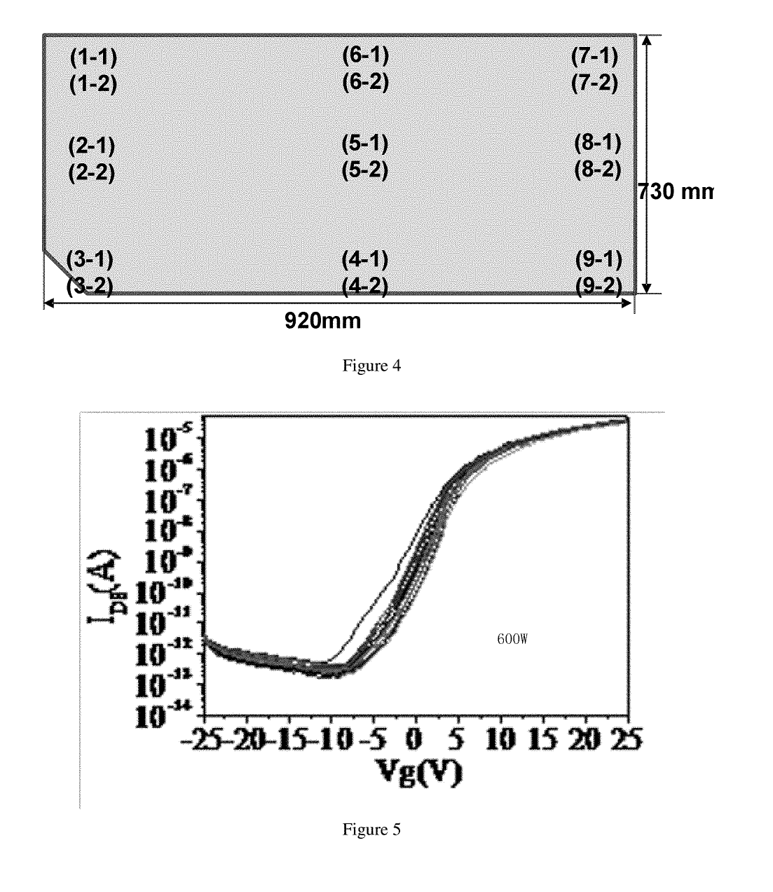

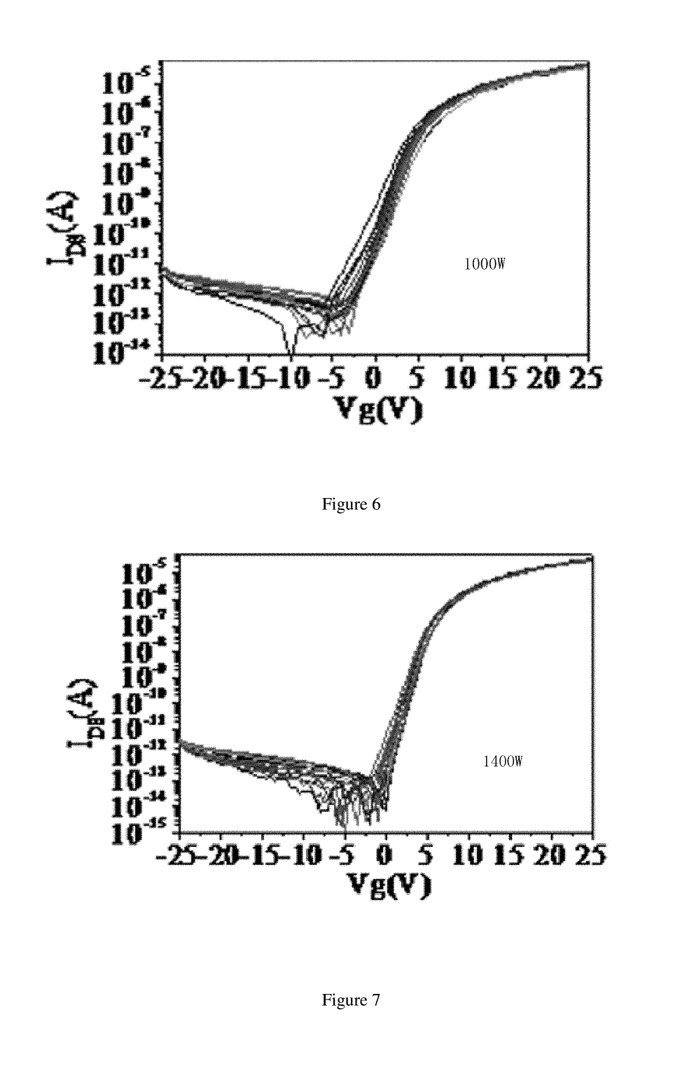

The above-described manufacturing process produces a 4.5-generation substrate, to effectively regulate the difference between the threshold voltages of the plurality of oxide TFTs, in the case when the chamber pressure, the spacing and the gas flow rate are kept constant, the power of the radio frequency is selected 600 W, 1000 W and 1400 W respectively to deposit silicon oxide thin films, then samples are hot-air annealed under the presence of compressed air at 350° C. for 1 hour. Eighteen TFT devices are tested on the 4.5-generation substrate. The testing points are shown in FIG. 4, and nine adjacent testing locations can be used to test for two TFT devices at each adjacent location. The current and voltage (IdVg) curve of the eighteen TFT devices is shown in FIG. 5 to FIG. 7, and then the threshold voltage (Vth) can be extracted from the IdVg curve of the series as shown in Table 1 below. As can be seen from Table 1, the ΔVth of the 1400 W sample is 1.17V, the ΔVth of the 1000 W sample is 2.24V, and the ΔVth of the 600 W sample is 3.46V. So, the regularity is that when ΔV this decreased with power of the radio frequency increasing obviously. If the difference between the threshold voltages of TFTs, the power of the radio frequency can be increased.

TABLE 1
Vth distribution table of deposition conditions in different power

| 1400 W | | | 1000 W | | | 600 W | | |
|---|---|---|---|---|---|---|---|---|
| (2.86, 2.82) | (3.08, 3.23) | (2.69, 2.72) | (1.87, 1.29) | (1.07, 1.82) | (1.05, 1.88) | (0.68, 0.58) | (0.99, 0.52) | (0.30, 1.00) |
| (3.34, 3.35) | (3.62, 3.58) | (3.03, 3.02) | (0.07, 1.25) | (1.75, 2.08) | (2.31, 2.27) | (1.61, 1.71) | (1.12, 1.52) | (−1.75, 0.23) |
| (3.51, 3.52) | (3.67, 3.63) | (2.82, 2.50) | (1.27, 1.42) | (1.76, 1.91) | (0.81, 1.16) | (−0.45, −0.66) | (0.49, 0.60) | (−0.32, 0.06) |

| | | |
|---|---|---|
| Maximum value: 3.67 V | Maximum value: 2.31 V | Maximum value: 1.71 V |
| Minimum value: 2.50 V | Minimum value: 0.07 V | Minimum value: −1.75 V |
| Average value: 3.17 V | Average value: 1.50 V | Average value: 0.46 V |
| ΔVth: 1.17 V | ΔVth: 2.24 V | ΔVth: 3.46 V |

It should be noticed that, the array substrate of the present invention is not limited to the above-described manufacturing process, but may also be manufactured by other processes, it shall not be construed as a limitation to the present invention.

In the present invention, the passivation layer is formed by radio frequency and annealing under the presence of compressed air after forming the oxide semiconductor material layer. By this way, it can regulate difference between threshold voltages of the plurality of oxide TFTs, and it can further reduce drift of threshold voltages of oxide semiconductor TFT, to achieve providing a base of a uniform display technology.

The present invention further provides a liquid crystal display panel, which comprises: a first substrate; a second substrate is arranged opposite to the first substrate; and a liquid crystal layer is arranged between the first substrate and the second substrate. Wherein the second substrate is any one of the above-described array substrates, therefore no additional description is given herebelow.

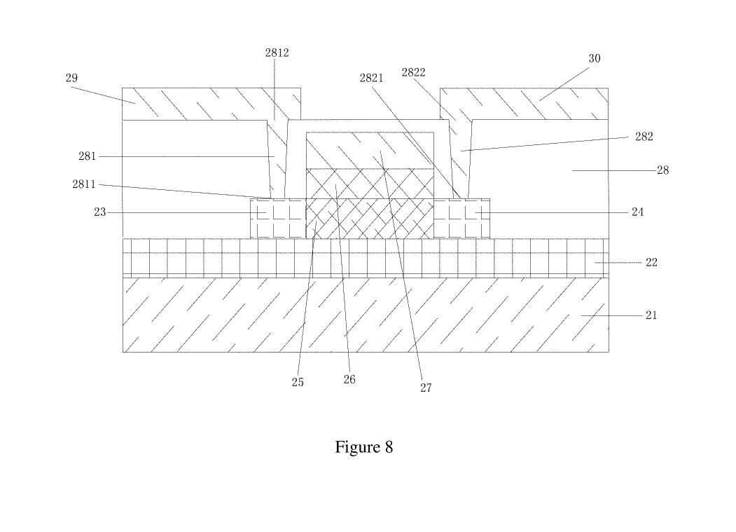

Referring to FIG. 8, FIG. 8 is an illustrational view of the array substrate in accordance with further embodiment of the present invention. On the array substrate, a plurality of oxide TFTs is arranged in an array, wherein the array substrate comprises: a substrate 21; an insulating buffer layer 22; an oxide semiconductor material layer, (which comprises a source region 23, drain region 24 and a channel region 25;) a gate insulating layer 26; a gate layer 27; an insulated interconnection layer 28; a source layer 29 and a drain layer 30.

The insulating buffer layer 22 covers the substrate 21, which may be made from silicon oxide.

The oxide semiconductor material layer comprises the channel region 25, the source region 23 and the drain region 24, and which is arranged on the insulating buffer layer 22, and wherein the source region 23 and the drain region 24 are located on both sides of the channel region 25 respectively, the source region 23 and the drain region 24 are formed by doping the oxide semiconductor material. Wherein the initial material of the source region 23 and the drain region 24 is an oxide semiconductor material and the final material is an oxide semiconductor material which has been doped to become a conductive material. In an embodiment, the basic principle of an oxide semiconductor material to become a conductive material after doping process may be: oxygen atoms in the oxide semiconductor material are captured and the oxygen atoms react with other substances, so the oxide semiconductor material becomes a conductive material because of the captured oxygen atoms. Herebelow, doping process, include, but are not limited to, plasma, ultraviolet light, metal oxidation, and so on. Of course, if the interconnection layer 28 is made from silicon nitride, when the interconnection layer 28 is deposited, hydrogen can capture oxygen atoms in the oxide semiconductor material and react with it, thereby the oxide semiconductor material becomes a conductor material. Materials of the oxide semiconductor material, include, but are not limited to amorphous indium-gallium-zinc-oxide.

The gate insulating layer 26 covers the channel region 25, and wherein the gate insulating layer 26 is formed by radio frequency and annealing under the presence of compressed air, so as to regulate difference between threshold voltages of the plurality of oxide TFTs. In a practical application, the difference between threshold voltages of the plurality of oxide TFTs can be regulated in accordance with actual needs by regulating the power of the radio frequency, annealing under the presence of compressed air, regulating the annealing temperature and the annealing time. The gate insulating layer 26 which may be made from silicon oxide.

The gate layer 27 covers the gate insulating layer 26. The gate layer 27 is made from metal conductor materials.

The insulated interconnection layer 28 covers the buffer layer 22, the source region 23, the gate layer 27, and the drain region 24, and a first contact hole 281 and a second contact hole 282 which pass through the interconnection layer 28 are arranged in the interconnection layer 28 respectively, a first end 2811 of the first contact hole 281 is connected to the source region 23 and a first end 2821 of the second contact hole 282 is connected to the drain region 24, wherein the material which filled in the first and second contact holes 281 and 282 is a transparent electrode material.

The source layer 29 and the drain layer 30 are arranged on the interconnection layer 28 separately and respectively and made from a transparent electrode material, wherein the source layer 29 is connected to the second end 2812 of the first contact hole 281, so as to achieve the electrical connection between the source layer 29 and the source region 23, and wherein the drain layer 30 is connected to the second end 2822 of the second contact hole 282, so as to achieve the electrical connection between the drain layer 30 and the drain region 24.

Wherein the power of the radio frequency is in the range of 400 W to 4000 W. Further, the power of the radio frequency is 600 W, 1000 W and 1400 W respectively.

Wherein the annealing temperature is in the range of 200 to 400° C. Further, the annealing temperature is 350° C.

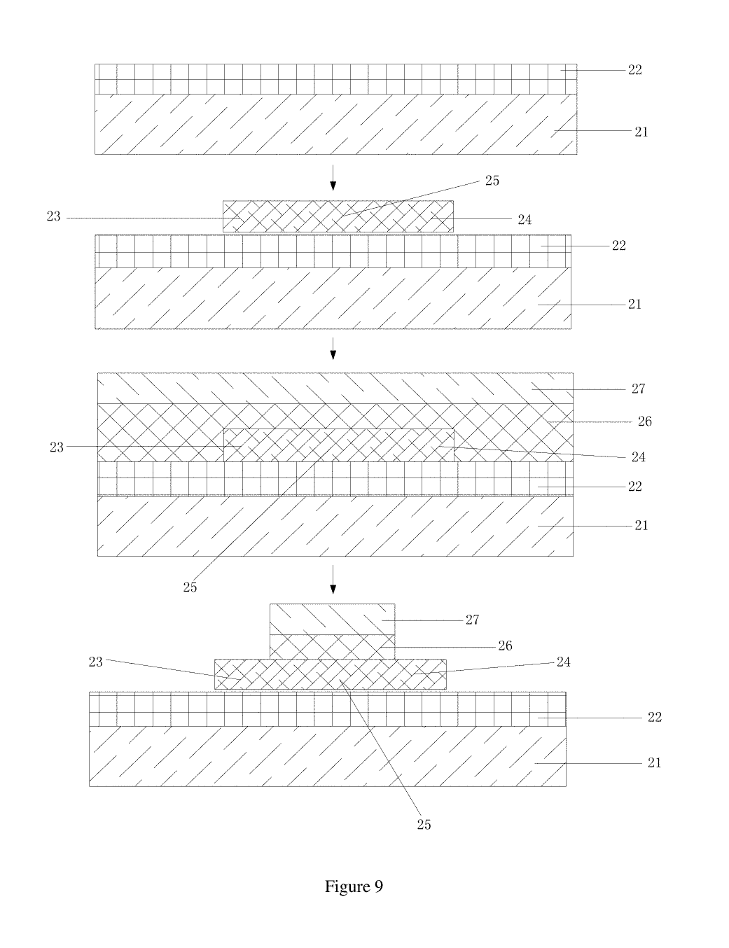

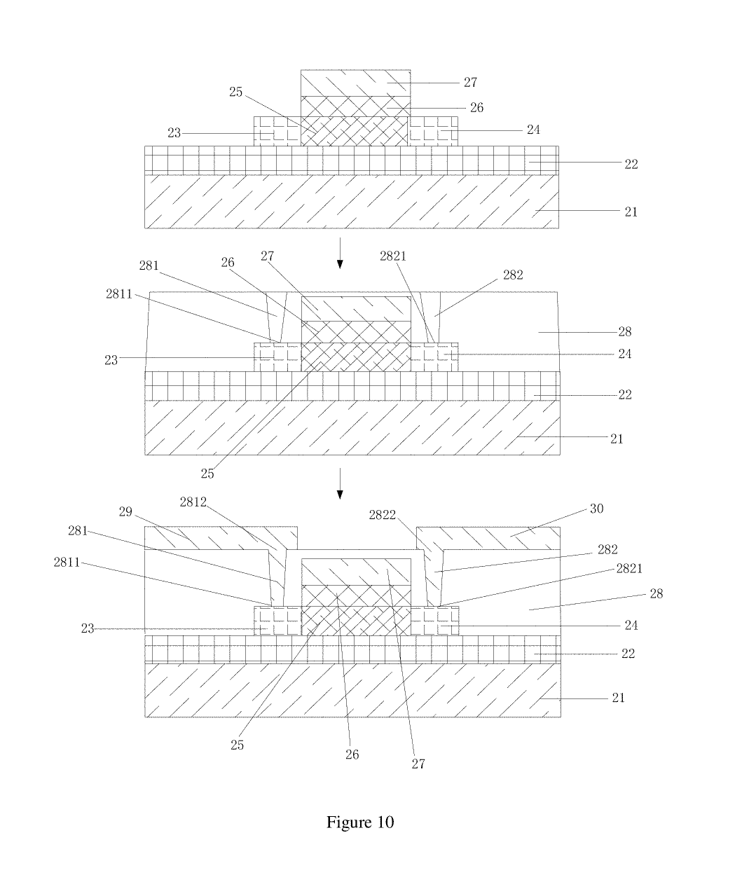

In an actual application, the array substrate described above can be manufactured by the following manufacturing process, as shown in FIGS. 9 and 10:

(1) depositing silicon oxide as the buffer layer 22 on the substrate 21 based on the CVD method;

(2) depositing an oxide semiconductor (e.g., amorphous indium-gallium-zinc-oxide) thin film on the buffer layer 22 based on the PVD method to form an oxide semiconductor material layer, and then forming a required amorphous indium-gallium-zinc-oxide pattern by a standard photolithographic process to obtain the source region 23, the drain region 24 and the channel region 25. At this moment, the source region 23 and the drain region 24 are still initial materials, e.g., oxide semiconductor materials;

(3) depositing the gate insulator layer 26 based on the CVD method, to effectively regulate difference between threshold voltages of a plurality of oxide TFTs, the gate insulator layer 26 is formed by radio frequency and annealing under the presence of compressed air;

(4) depositing the metal gate layer 27 based on the PVD method, and then coating a photoresist to form a pattern, and etching metal layer and insulator layer which are not protected by the photoresist by a dry etch method or a wet-etch method;

(5) doping an exposed oxide semiconductor material by such as plasma, ultraviolet light, metal oxidation and so on, to become a conductor treated as the source region 23 and the drain region 24 (if the interconnection layer is made from silicon nitride, this step may be omitted;)

(6) depositing silicon oxide or silicon nitride to form the interconnection layer 28, and the interconnection layer 28 is opened to obtain the contact hole 281 and the contact hole 282 located in the source region 23 and drain region 24 by a standard photolithography process;

(7) depositing a metal thin film based on the PVD method, and patterning to form source and drain electrode patterns to obtain the source layer 29 and the drain layer 30;

Further, the following two steps may be included:

(8) depositing silicon oxide by the PECVD method to obtain the over coat, or depositing an organic over coat by the coating method, and the over coat and the passivation layer is opened to obtain the contact hole located in the drain electrode by a standard photolithography process;

(9) depositing indium tin oxide and patterning by a standard photolithography process to form pixel electrodes located in which connected to the drain electrode, thereby the manufacturing process of the array substrate is completed.

In the present invention, the gate insulator layer is formed by radio frequency and annealing under the presence of compressed air after forming the oxide semiconductor material layer. By this way, it can regulate difference between threshold voltages of the plurality of oxide TFTs, and it can further reduce drift of threshold voltages of oxide semiconductor TFT, to achieve providing a base of a uniform display technology.

The present invention further provides a liquid crystal display panel, which comprises: a first substrate; a second substrate is arranged opposite to the first substrate; and a liquid crystal layer is arranged between the first substrate and the second substrate. Wherein the second substrate is any one of the above-described array substrates, therefore no additional description is given herebelow.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

1. An array substrate, and on the array substrate, a plurality of oxide thin film transistors arranged in an array, wherein the array substrate comprises:
a substrate;
a gate layer formed on the substrate;
a gate insulating layer covering the substrate and the gate layer;
an oxide semiconductor material layer formed on the gate insulating layer and located directly above the gate layer;
a source layer and a drain layer formed on the gate insulating layer separately and respectively, and covering a part of the oxide semiconductor material layer respectively, in a way so that source layer and the drain layer located on both sides of the oxide semiconductor material layer respectively;
a passivation layer covering the source layer, the drain layer, and the oxide semiconductor material layer, the passivation layer formed by radio frequency and annealing under the presence of compressed air, so as to regulate difference between threshold voltages of the plurality of oxide thin film transistors;
an over coat covering the passivation layer, a contact hole which passing through the over coat arranged in the over coat, a first end of the contact hole extending and passing through the passivation layer and connected to the drain layer, the material which filled in the contact hole being a transparent electrode material; and
a pixel electrode layer formed on the over coat and made from a transparent electrode material, the pixel electrode layer connected to the second end of the contact hole, so as to achieve the electrical connection between the drain layer and the pixel electrode layer.

2. The substrate as recited in claim 1, wherein the power of the radio frequency is in the range of 400 W to 4000 W.

3. The substrate as recited in claim 2, wherein the power of the radio frequency is 600 W, 1000 W and 1400 W respectively.

4. The substrate as recited in claim 1, wherein the annealing temperature is in the range of 200 to 400° C.

5. A liquid crystal display panel which comprising:
a first substrate;
a second substrate arranged opposite to the first substrate, and on the second substrate, a plurality of oxide thin film transistors arranged in an array, wherein the second substrate comprises:
a substrate;
a gate layer arranged on the substrate;
a gate insulating layer covering the substrate and the gate layer;
an oxide semiconductor material layer arranged on the gate insulating layer and located directly above the gate layer;
a source layer and a drain layer arranged on the gate insulating layer separately and respectively, and covering a part of the oxide semiconductor material layer respectively, in a way so that source layer and the drain layer located on both sides of the oxide semiconductor material layer respectively;
a passivation layer covering the source layer, the drain layer, and the oxide semiconductor material layer, the passivation layer formed by radio frequency and annealing under the presence of compressed air, so as to regulate difference between threshold voltages of the plurality of oxide thin film transistors;
an over coat covering the passivation layer, a contact hole which passing through the over coat arranged in the over coat, a first end of the contact hole extending and passing through the passivation layer and connected to the drain layer, the material which filled in the contact hole being a transparent electrode material;
a pixel electrode layer arranged on the over coat and made from a transparent electrode material, the pixel electrode layer connected to the second end of the contact hole, so as to achieve the electrical connection between the drain layer and the pixel electrode layer; and
a liquid crystal layer arranged between the first substrate and the second substrate.

6. An array substrate, and on the array substrate, a plurality of oxide thin film transistors arranged in an array, wherein the array substrate comprises:
a substrate;
an insulating buffer layer covering the substrate;
an oxide semiconductor material layer, which comprising a channel region, a source region, and a drain region, the oxide semiconductor material layer arranged on the insulating buffer layer, and wherein the source region and the drain region are located on both sides of the channel region respectively, the source region and the drain region formed by doping the oxide semiconductor material;
a gate insulating layer covering the channel region, and wherein the gate insulating layer is formed by radio frequency and annealing under the presence of compressed air, so as to regulate difference between threshold voltages of the plurality of oxide thin film transistors;
a gate layer covering the gate insulating layer;
an insulated interconnection layer covering the buffer layer, the source region, the gate layer, and the drain region, and a first contact hole and a second contact hole which passing through the interconnection layer arranged in the interconnection layer respectively, a first end of the first contact hole connected to the source region and a first end of the second contact hole connected to the drain region, wherein the material which filled in the first and second contact holes is a transparent electrode material; and
a source layer and a drain layer arranged on the interconnection layer separately and respectively and made from a transparent electrode material, wherein the source layer is connected to the second end of the first contact hole, so as to achieve the electrical connection between the source layer and the source region, and wherein the drain layer is connected to the second end of the second contact hole, so as to achieve the electrical connection between the drain layer and the drain region.

7. The array substrate as recited in claim 6, wherein the power of the radio frequency is in the range of 400 W to 4000 W.

8. The array substrate as recited in claim 7, wherein the power of the radio frequency is 600 W, 1000 W and 1400 W respectively.

9. The substrate as recited in claim 6, wherein the annealing temperature is in the range of 200 to 400° C.
